(19) United States
(12) Patent Application Publication
(10) Pub. No.: US 2022/0231149 A1
(43) Pub. Date: Jul. 21, 2022

(54) METHOD OF MANUFACTURING SEMICONDUCTOR DEVICE

(71) Applicant: Japan Display Inc., Tokyo (JP)

(72) Inventors: Akihiro HANADA, Tokyo (JP); Kentaro MIURA, Tokyo (JP); Hajime WATAKABE, Tokyo (JP); Masashi TSUBUKU, Tokyo (JP); Toshinari SASAKI, Tokyo (JP); Takaya TAMARU, Tokyo (JP); Takeshi SAKAI, Tokyo (JP)

(73) Assignee: Japan Display Inc., Tokyo (JP)

(21) Appl. No.: 17/575,635

(22) Filed: Jan. 14, 2022

(30) Foreign Application Priority Data
Jan. 15, 2021 (JP) 2021-005017

(51) Int. Cl. H01L 29/66; H01L 21/02; H01L 29/40; H01L 21/3115

(52) U.S. Cl. CPC H01L 29/66969; H01L 21/02321; H01L 29/4908; H01L 21/3115; H01L 29/401

(57) ABSTRACT

According to one embodiment, a method of manufacturing a semiconductor device comprises forming an oxide semiconductor layer, forming a gate insulating layer in contact with the oxide semiconductor layer and covering the oxide semiconductor layer, and forming a gate electrode on the gate insulating layer so as to overlap the oxide semiconductor layer, and injecting boron through the gate electrode and the gate insulating layer after forming the gate electrode, wherein a boron concentration included in a region of the gate insulating layer overlapping the gate electrode is in a range of 1E+16 [atoms/cm³] or more.

### CROSS-REFERENCE TO RELATED APPLICATIONS

This application is based upon and claims the benefit of priority from Japanese Patent Application No. 2021-005017, filed Jan. 15, 2021, the entire contents of which are incorporated herein by reference.

### FIELD

An embodiment of the present invention relates to a method of manufacturing a semiconductor device.

### BACKGROUND

In a display device, a technique has been proposed in which a transistor having an oxide semiconductor is provided in a pixel circuit in a display area, and a transistor having a silicon semiconductor is provided in a drive circuit in a peripheral area.

### BRIEF DESCRIPTION OF THE DRAWINGS

FIG. 1 is a plan view showing a configuration of a display device including a semiconductor device according to the present embodiment.

FIG. 2 is a conceptual cross-sectional view of a display device including the semiconductor device of the embodiment.

FIG. 3 is a cross-sectional view showing a manufacturing process of a transistor.

FIG. 4 is a cross-sectional view of a transistor.

FIG. 5 is a diagram showing a secondary ion mass spectrometry (SIMS) profile of layers constituting a transistor.

FIG. 6 is a diagram showing a temporal change in transistor characteristics under an acceleration test.

FIG. 7 is a diagram showing a temporal change in transistor characteristics under an acceleration test.

FIG. 8 is a diagram showing a temporal change in transistor characteristics under an acceleration test.

FIG. 9 is a diagram showing a temporal change in transistor characteristics under an acceleration test.

FIG. 10 is a diagram showing a temporal change in a drain current when a constant current is continuously carried through a transistor.

FIG. 11 is a diagram showing a temporal change in a drain current when a constant current is continuously carried through a transistor.

FIG. 12 is a diagram showing the configuration of a stack of a transistor.

FIG. 13 is a view showing a simulation result of boron injection in the configuration of the stack.

FIG. 14 is a cross-sectional view showing a configuration example of a semiconductor device according to an embodiment.

FIG. 15 is a cross-sectional view showing a manufacturing process of a transistor.

FIG. 16 is a cross-sectional view showing a manufacturing process of the transistor.

FIG. 17 is a cross-sectional view showing a manufacturing process of the transistor.

FIG. 18 is a cross-sectional view showing a manufacturing process of the transistor.

FIG. 19 is a cross-sectional view showing a configuration example of a semiconductor device according to an embodiment.

FIG. 20 is a cross-sectional view showing a manufacturing process of the transistor.

### DETAILED DESCRIPTION

According to one embodiment, a method of manufacturing a semiconductor device comprises forming an oxide semiconductor layer; forming a gate insulating layer in contact with the oxide semiconductor layer and covering the oxide semiconductor layer; and forming a gate electrode on the gate insulating layer so as to overlap the oxide semiconductor layer; and injecting boron through the gate electrode and the gate insulating layer after forming the gate electrode, wherein a boron concentration included in a region of the gate insulating layer overlapping the gate electrode is in a range of 1E+16 [atoms/cm³] or more.

According to another embodiment, a method of manufacturing a semiconductor device comprises forming a first insulating layer; injecting boron into the first insulating layer; forming an oxide semiconductor layer in contact with the first insulating layer into which the boron is injected; forming a second insulating layer in contact with the oxide semiconductor layer and covering the first insulating layer and the oxide semiconductor layer; injecting boron into the second insulating layer; and forming a gate electrode on the second insulating layer into which the boron is injected, the gate electrode being overlapping the oxide semiconductor layer, wherein a boron concentration included in the first insulating layer and the second insulating layer is in a range of 1E+16 [atoms/cm³] or more.

According to another embodiment, a method of manufacturing a semiconductor device comprises forming a gate electrode; forming a first insulating layer covering the gate electrode; injecting boron into the first insulating layer; forming an oxide semiconductor layer in contact with the first insulating layer into which the boron is injected; forming a source electrode and a drain electrode overlapping a part of the oxide semiconductor layer; forming a second insulating layer in contact with the oxide semiconductor layer and covering the oxide semiconductor layer, the source electrode, and the drain electrode; and injecting boron into the second insulating layer, wherein a boron concentration included in the first insulating layer and the second insulating layer is in a range of 1E+16 [atoms/cm³] or more.

According to the present embodiment, it is possible to provide a method of manufacturing a semiconductor device with improved reliability.

Embodiments will be described hereinafter with reference to the accompanying drawings. The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

An embodiment will now de described in detail with reference to accompanying drawings.

In the following descriptions, for example, a first direction X, a second direction Y and a third direction Z are orthogonal to each other, but may intersect at an angle other than ninety degrees. A direction forwarding a tip of an arrow indicating the third direction Z is referred to as “upward” and a direction forwarding oppositely from the tip of the arrow is referred to as “downward”.

With such expressions “a second member above a first member” and “a second member below a first member”, the second member may be in contact with the first member or may be remote from the first member. In the latter case, a third member may be interposed between the first member and the second member. On the other hand, with such expressions “a second member on a first member” and “a second member on a first member”, the second member is meant to be in contact with the first member.

In addition, it is assumed that there is an observation position to observe the semiconductor substrate on a tip side of an arrow in a third direction Z, and viewing from this observation position toward the X-Y plane defined by the first direction X and the second direction Y is referred to as a planar view. Viewing a cross section of the semiconductor substrate in an X-Z plane defined by the first direction X and the third direction Z or a Y-Z plane defined by the second direction Y and the third direction Z is referred to as a cross-sectional view.

### Embodiment

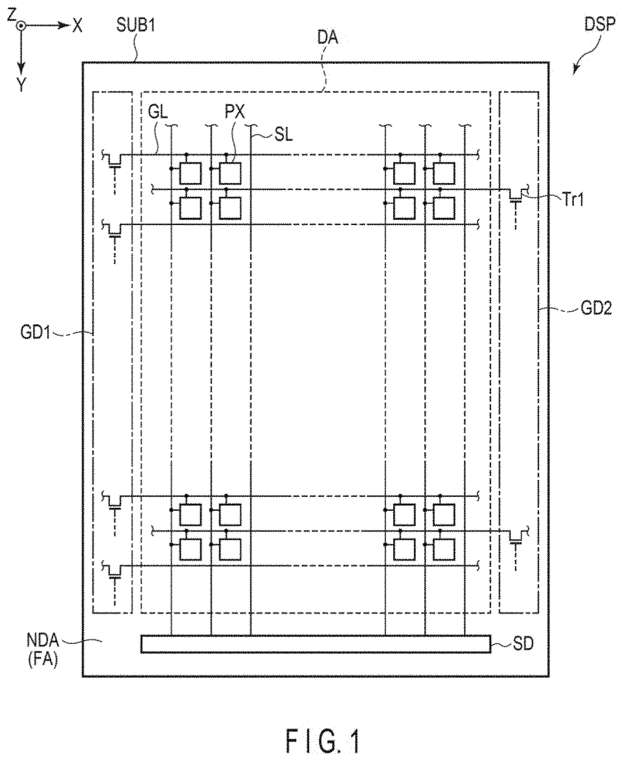

FIG. 1 is a plan view showing a configuration of a display device including a semiconductor device according to the present embodiment. A display device DSP includes a display area DA in which an image is displayed and a peripheral area (non-display area) NDA around the display area DA. In the example illustrated in FIG. 1, the peripheral area NDA is formed in a frame shape surrounding the display area DA. The peripheral area NDA is also referred to as a frame area FA.

The display device DSP includes gate drivers GD1 and GD2 and a source driver SD in the peripheral area NDA. The gate drivers GD1 and GD2 include a transistor Tr1. As described above, the gate drivers GD1 and GD2 are formed on the same substrate together with the components in the display area DA.

The display device DSP includes a plurality of pixels PX, a plurality of scanning lines GL, and a plurality of signal lines SL in the display area DA. The plurality of pixels PX is arranged in a matrix in the first direction X and the second direction Y.

The plurality of scanning lines GL extends along the first direction X and is arranged in the second direction Y spaced apart from each other. The scanning line GL is sometimes referred to as a gate line. The scanning line GL is electrically connected to the gate drivers GD1 and GD2. For example, the odd-numbered scanning line GL is connected to the gate driver GD1 and the even-numbered scanning line GL is connected to the gate driver GD2. The scanning lines GL are driven by the gate drivers GD1 and GD2.

The plurality of signal lines SL extends along the second direction Y and is arranged in the first direction X spaced apart from each other. The signal line SL is sometimes referred to as a source line. In the display area DA, the plurality of signal lines SL intersects with the plurality of scanning lines GL. The signal line SL is electrically connected to the source driver SD. The signal lines SL are driven by the source driver SD.

The pixels PX each include a transistor Tr2 and a pixel electrode PE, which will be described later. Although the details will be described later, the transistor Tr1 and the transistor Tr2 are formed of, for example, a thin-film transistor (TFT). The transistor Tr2 is electrically connected to the scanning line GL and the signal line SL. The scanning line GL is electrically connected to the transistor Tr2 in each of the pixels PX arranged in the first direction X. The signal line SL is electrically connected to the transistor Tr2 in each of the pixels PX arranged in the second direction Y.

In the present embodiment, the transistors Tr1 and Tr2 are sometimes referred to as a semiconductor device. A substrate including the transistors Tr1 and Tr2, various wiring lines, and various electrodes is sometimes referred to as a semiconductor device.

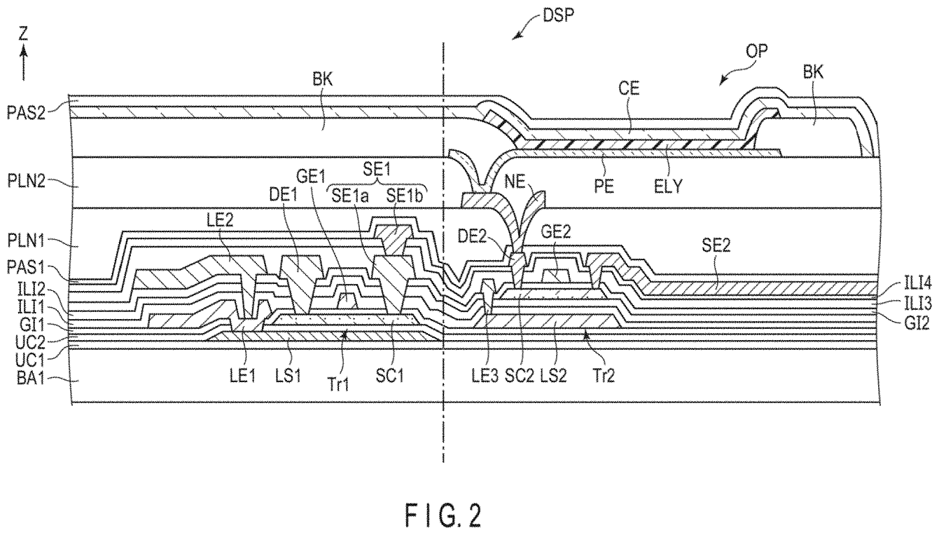

FIG. 2 is a conceptual cross-sectional view of the display device including the semiconductor device of the embodiment. Hatching of a part of components is omitted to make the drawings easier to read. The display device DSP shown in FIG. 2 includes a base material BA1, an insulating layer UC1, a light-shielding layer LS1, an insulating layer UC2, the transistor Tr1, an insulating layer ILI1, an insulating layer ILI2, a light-shielding layer LS2, the transistor Tr2, an insulating layer ILI3, an insulating layer ILI4, an insulating layer PAS1, an insulating layer PLN1, a connection electrode NE, an insulating layer PLN2, the pixel electrode PE, an organic EL layer ELY, a common electrode CE, and an insulating layer PAS2. The transistors Tr1 and Tr2 are also referred to as a first thin-film transistor and a second thin-film transistor, respectively.

The material of the base material BA1 is glass or resin. Examples of such a resin include a polyimide resin and an acrylic resin.

The insulating layer UC1 blocks impurities derived from glass and the like, and is formed of, for example, a single layer or a stack of silicon oxide or silicon nitride.

The light-shielding layer LS1 has a function that shields the semiconductor layer of the transistor Tr1 from light. In the case in which the light-shielding layer LS1 is a metal layer, the light-shielding layer LS1 may have a function as the back gate of the transistor Tr1. In that case, it can be said that the light-shielding layer LS1 is included in the transistor Tr1.

On the light-shielding layer LS1 and the insulating layer UC1, the insulating layer UC2 is provided. The insulating layer UC2 only has to be made of the same material as the insulating layer UC1.

On the insulating layer UC2, a semiconductor layer SC1 that is the active layer of the transistor Tr1 is provided. The semiconductor layer SC1 is made of polycrystalline silicon. The semiconductor layer SC1 is sometimes referred to as a first semiconductor layer or a polycrystalline silicon layer.

The semiconductor layer SC1 has a channel forming region overlapping a gate electrode GE1, a source region overlapping a source electrode SE1, and a drain region overlapping a drain electrode DE1.

On the semiconductor layer SC1 and the insulating layer UC2, an insulating layer GI1 is provided. The insulating layer GI1 is made of, for example, silicon oxide. The insulating layer GI1 is the gate insulating layer of the transistor Tr1.

On the insulating layer GI1, the gate electrode GE1 of the transistor Tr1, an electrode LE1, and the light-shielding layer LS2 are provided In other words, the insulating layer GI1 is provided between the semiconductor layer SC1 and the gate electrode GE1. The gate electrode GE1, the electrode LE1, and the light-shielding layer LS2 are formed of, for example, a molybdenum-tungsten alloy (MoW) or a stack of an aluminum alloy sandwiched between titanium.

The electrode LE1 is connected to the light-shielding layer LS1 through contact holes provided in the insulating layers UC2 and GI1. As described above, in the case in which the light-shielding layer LS1 functions as the back gate of the transistor Tr1, a signal is input through the electrode LE1.

The light-shielding layer LS2 shields the active layer of the transistor Tr2 from light. The light-shielding layer LS2 may function as the back gate of the transistor Tr2. In that case, it can be said that the light-shielding layer LS2 is included in the transistor Tr2.

On the insulating layer GI1, the insulating layer ILI1 is provided covering the gate electrode GE1, the electrode LE1, and the light-shielding layer LS2. The insulating layer ILI1 is made of, for example, silicon nitride.

On the insulating layer ILI1, the insulating layer ILI2 is provided. The insulating layer ILI2 is made of, for example, silicon oxide. The insulating layers ILI1 and ILI2 function as the interlayer insulating layer of the transistor Tr1. The insulating layers ILI1 and ILI2 also function as an insulating layer between the light-shielding layer LS2 and a semiconductor layer SC2.

On the insulating layer ILI2, the semiconductor layer SC2 that is the active layer of the transistor Tr2 is provided overlapping the light-shielding layer LS2. The semiconductor layer SC2 is made of an oxide semiconductor. The semiconductor layer SC2 is sometimes referred to as a second semiconductor layer or an oxide semiconductor layer. Oxide semiconductors include Indium Gallium Zinc Oxide (IGZO), Indium Tin Zinc Oxide (ITZO), Zinc Oxide Nitride (ZnON), Indium Gallium Oxide (IGO), and the like.

The semiconductor layer SC2 has a channel forming region overlapping a gate electrode GE2, a source region overlapping a source electrode SE2, and a drain region overlapping a drain electrode DE2. The gate electrode GE2 is electrically connected to the scanning line GL. The gate electrode GE2 may be integrally formed with the scanning line GL.

On the semiconductor layer SC2 and the insulating layer ILI2, an insulating layer GI2 is provided. The insulating layer GI2 is formed of, for example, silicon oxide. The insulating layer GI2 functions as the gate insulating layer of the transistor Tr2. It can be said that the semiconductor layer SC2 is provided between the insulating layers ILI2 and GI2.

The film thickness of the insulating layer GI2 may be, for example, about 100 nm. The film thicknesses of the insulating layers ILI1 and ILI2 are, for example, about 300 nm. However, the film thicknesses of the insulating layers ILI1, ILI2, and GI2 are non-limiting. The combined thickness of the insulating layers ILI1 and ILI2 is preferably larger than the thickness of the insulating layer GI2. In other words, the insulating layer GI2 located on the semiconductor layer SC2 is thinner than the film thicknesses of the insulating layers ILI1 and ILI2 located under the semiconductor layer SC2.

In addition, the film thickness of the insulating layer GI2 is preferably about the same as the film thickness of the insulating layer GI1.

On the insulating layer GI2, there are provided the gate electrode GE2 overlapping the channel forming region of the semiconductor layer SC2, a source electrode SE1a overlapping the source region of the semiconductor layer SC1, the drain electrode DE1 overlapping the drain region of the semiconductor layer SC1, an electrode LE2 connected to the electrode LE1, and an electrode LE3 connected to the light-shielding layer LS2. In other words, the insulating layer GI2 is provided between the semiconductor layer SC2 and the gate electrode GE2. The gate electrode GE2, the source electrode SE1a, the drain electrode DE1, the electrode LE2, and the electrode LE3 may be formed of a material described later.

The insulating layer ILI3 is provided covering the insulating layer GI2, the gate electrode GE2, the source electrode SE1a, the drain electrode DE1, the electrode LE2, and the electrode LE3. The insulating layer ILI4 is provided on the insulating layer ILI3. The insulating layers ILI3 and ILI4 are formed of silicon nitride and silicon oxide, respectively.

On the insulating layer ILI4, there are provided a source electrode SE1b connected to the source electrode SE1a, the source electrode SE2 overlapping the source region of the semiconductor layer SC2, and the drain electrode DE2 overlapping the drain region of the semiconductor layer SC2. The source electrode SE1b, the source electrode SE2, and the drain electrode DE2 are formed of, for example, a stacked film of an aluminum alloy layer sandwiched between titanium films (a stacked film of titanium, aluminum, and titanium (Ti/Al/Ti)).

The source electrodes SE1a and SE1b are combined to form the source electrode SE1. The source electrode SE1b may be integrally formed with the signal line SL. The source electrode SE1 (the source electrodes SE1a and SE1b) may be integrally formed with the signal line SL.

The insulating layer PAS1 is provided covering the insulating layer ILI4, the source electrode SE1b, the source electrode SE2, and the drain electrode DE2. The insulating layer PAS1 is made of, for example, silicon oxide.

The insulating layer PLN1 is provided covering the insulating layer PAS1. The insulating layer PLN1 is made of an organic insulating material, for example, polyimide.

On the insulating layer PLN1, the connection electrode NE connected to the drain electrode DE2 is provided. The connection electrode NE is formed of, for example, a stacked film having an aluminum alloy layer sandwiched between titanium films. In the present embodiment, although the configuration in which the connection electrode NE is provided is described, the present invention is not limited to this. A configuration may be provided in which the connection electrode NE is not provided, and the pixel electrode PE, described later, is directly connected to the drain electrode DE2.

The insulating layer PLN2 is provided covering the insulating layer PLN1 and the connection electrode NE. The insulating layer PLN2 is made of an organic insulating material, for example, polyimide. The insulating layers PLN1 and PLN2 have a function that planarizes the unevenness of a substrate SUB1 caused by a transistor or the like.

On the insulating layer PLN2, the pixel electrode PE connected to the connection electrode NE is provided. As described above, the pixel electrode PE may be connected to the drain electrode DE2.

The pixel electrode PE may have a stacked structure of a first conductive layer having reflectivity and a second conductive layer having translucency. For example, a configuration may be provided in which silver (Ag) is used as the material of the first conductive layer, indium zinc oxide (IZO) is used as the material of the second conductive layer, and the pixel electrode PE is formed of a stacked structure in which IZO, Ag, and IZO are stacked in this order.

Between the adjacent pixel electrodes PE, a bank BK (also referred to as a convex portion, a rib, or a barrier wall) is provided. As the material of the bank BK, the same organic material as the material of the insulating layers PLN1 and PLN2 is used. The bank BK is opened so as to expose a part of the pixel electrode PE. In addition, the end portion of an opening portion OP preferably has a gentle taper shape. When the end portion of the opening portion OP has a steep shape, poor coverage occurs in the organic EL layer ELY, which is formed later.

The organic EL layer ELY is provided between the adjacent bank BK, overlapping the pixel electrode PE. The organic EL layer ELY includes a hole-injection layer, a hole-transport layer, an electron-blocking layer, a light-emitting layer, a hole-blocking layer, an electron-transport layer, an electron-injection layer, and the like. In the present specification, the organic EL layer ELY is also referred to as an organic material layer. The organic EL layer ELY includes at least a light-emitting layer, and other layers may be appropriately provided as needed.

The common electrode CE is provided covering the organic EL layer ELY and the bank BK. The common electrode CE may include, for example, a first layer and a second layer. The second layer may have a higher transmittance than that of the first layer. For example, a thin film of a magnesium-silver (MgAg) alloy or an ytterbium-silver (YbAg) alloy may be formed as the first layer. As the second layer, a transparent electrode, for example, indium tin oxide (ITO) or indium zinc oxide (IZO) is formed.

In the present embodiment, the pixel electrode PE serves as an anode (a positive electrode) and the common electrode CE serves as a cathode (a negative electrode). The light emitted from the organic EL layer ELY is taken out upward. That is, the display device DSP has a top emission structure.

The insulating layer PAS2 is provided covering the common electrode CE. The insulating layer PAS2 has a function that stops moisture from entering the organic EL layer ELY from the outside and has an optical adjustment function. As the insulating layer PAS2, one having a high gas barrier property is suitable. The insulating layer PAS2 may be, for example, a stack of an organic insulating layer and an inorganic insulating layer containing nitrogen. Alternatively, an example of the insulating layer PAS2 includes an insulating layer in which an organic insulating layer is sandwiched between two inorganic insulating layers containing nitrogen. The insulating layer PAS2 may have a structure in which two inorganic insulating layers are stacked. Examples of the material of the organic insulating layer include acrylic resins, epoxy resin, and polyimide resins. Examples of the material of the inorganic insulating layer containing nitrogen include silicon nitride and aluminum nitride.

Although not illustrated in the drawing, an organic resin layer or a base material BA2 facing the base material BA1 may be further provided on the insulating layer PAS2.

The semiconductor layer SC2 of the transistor Tr2 is sandwiched between the insulating layers ILI2 and GI2 that are silicon oxide films. The reliability of the transistor Tr2 might be degraded due to the defect level existing in the silicon oxide films on the upper and lower sides of the semiconductor layer SC2 that is an active layer. The defect level is primarily due to the excessive oxygen of the silicon oxide film. Such a defect functions as an electron trap while the transistor Tr2 is driven. As a result, this degrades the reliability of the transistor Tr2.

Hydrogen termination can also be used to repair defects in the silicon oxide film. However, in the transistor in which the oxide semiconductor layer is the active layer, a threshold value Vth might be greatly depleted due to excessive hydrogen. An extreme Vth shift (depletion) might cause abnormal operation of the display device DSP including the transistor Tr2. Therefore, in the display device DSP, termination of the silicon oxide film with hydrogen is not preferable.

In the present embodiment, the insulating layers ILI2 and GI2, which are silicon oxide films, are terminated with boron instead of hydrogen. As a result, it is possible to repair the defect of the silicon oxide film without causing the depletion of the transistor Tr2. It is possible to intend to improve the reliability of the transistor Tr2 and it is possible to improve the reliability of the display device DSP including the transistor Tr2.

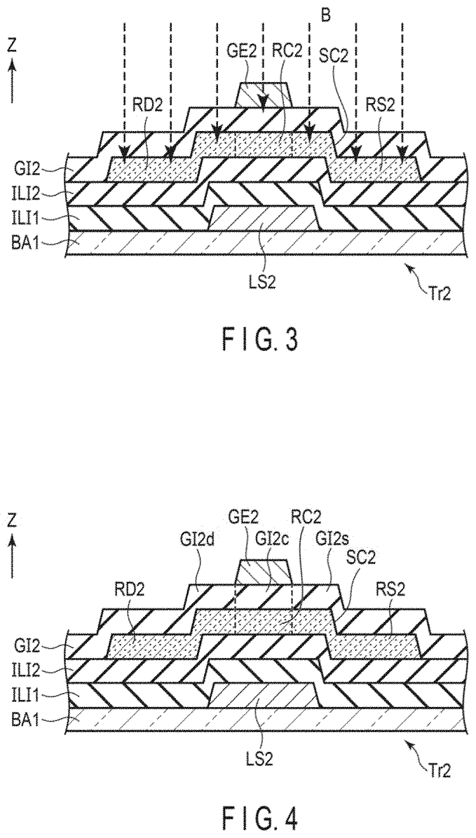

FIG. 3 is a cross-sectional view showing a manufacturing process of the transistor. In the transistor Tr2 shown in FIG. 3, the light-shielding layer LS2, the insulating layer ILI1, the insulating layer ILI2, the semiconductor layer SC2, the insulating layer GI2, and the gate electrode GE2 are formed on the base material BA1. Similarly to FIG. 2, an insulating layer may be provided between the base material BA1 and the light-shielding layer LS2.

After forming the gate electrode GE2, the above-described boron B is injected. At this time, the applied voltage (also referred to as an acceleration voltage) of boron B is set as a voltage that causes boron B to reach the semiconductor layer SC2 or the insulating layer ILI2, which is a layer below the semiconductor layer SC2, in the region of the semiconductor layer SC2 that does not overlap the gate electrode GE2. At this voltage, in a region of the semiconductor layer SC2 overlapping the gate electrode GE2, boron B is injected into the insulating layer GI2 through the gate electrode GE2.

The insulating layer GI2 is a silicon oxide film as described above, and the film thickness of the insulating layer GI2 may be in a rage of, for example, 50 nm or more and 200 nm or less. In the insulating layer GI2 having a film thickness in such a range, boron B is injected into the semiconductor layer SC2 through the insulating layer GI2 in a region that does not overlap the gate electrode GE2. As described above, boron B may reach the insulating layer ILI2.

In the case in which the insulating layer GI2 has the above-described film thickness, in a region of the semiconductor layer SC2 overlapping the gate electrode GE2, the gate electrode GE2 as well as the insulating layer GI2 function as a mask, and thus no boron B is injected.

FIG. 4 is a cross-sectional view of the transistor. With the injection of boron B, a defect level is formed in the semiconductor layer SC2 in the region of the semiconductor layer SC2 that does not overlap the gate electrode GE2. In this region, the defect level is formed to decrease resistance. The low resistance region is used as a source region RS2 and a drain region RD2.

In the insulating layer GI2, boron B is injected to decrease excessive oxygen in a region GI2c overlapping the gate electrode GE2. As a result, it possible to suppress degradation in the reliability of the transistor Tr2.

The region GI2c overlaps a channel forming region RC2. In the insulating layer GI2, a region that does not overlap the gate electrode GE2 and overlaps the source region RS2 is GI2s, and a region that overlaps the drain region RD2 is GI2d.

The concentration of boron B in the region GI2c may be in a range of 1E+16 [atoms/cm³] or more. In the present embodiment, E means a power of 10, for example, 1E+16 means 1×10¹⁶ (1×10 to the power of 16). The term [atoms/cm³ (atoms/cubic cm)] is the number of atoms per cubic centimeter. In the injection process of boron B shown in FIG. 3, the applied voltage is determined such that the concentration of boron B in the region GI2c is as described above.

The gate electrode GE2 is formed of titanium (Ti), aluminum (Al), molybdenum (Mo), tungsten (W), indium tin oxide (ITO), indium zinc oxide (IZO), an alloy containing these, or a stack of these.

The region of the insulating layer GI2 in contact with the semiconductor layer SC2 is formed of silicon oxide. However, the region that is not in contact with the semiconductor layer SC2 may be formed of silicon oxide nitride, silicon nitride, aluminum oxide, or a stacked structure of these, instead of silicon oxide.

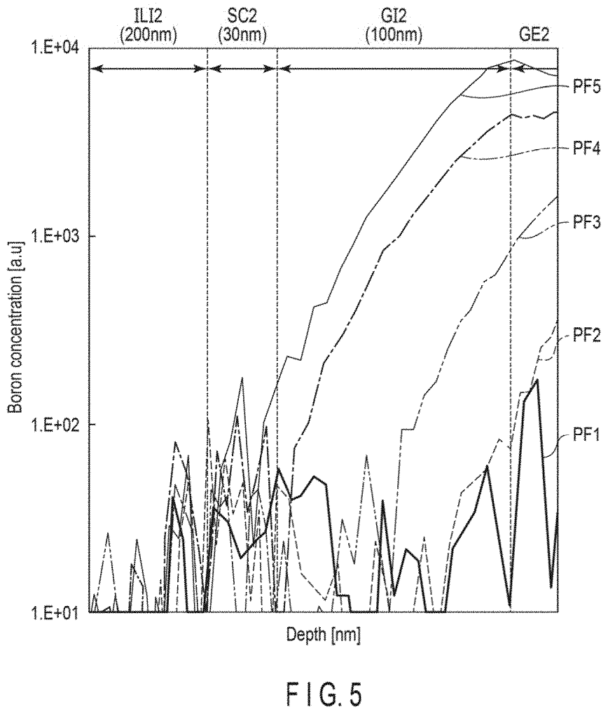

FIG. 5 is a diagram showing a secondary ion mass spectrometry (SIMS) profile of layers constituting a transistor.

FIG. 5 shows the SIMS profile of boron B in the insulating layer ILI2, the semiconductor layer SC2, the insulating layer GI2, and the gate electrode GE2 of the transistor Tr2. The insulating layer ILI2, the semiconductor layer SC2, the insulating layer GI2, and the gate electrode GE2 are stacked in this order from the bottom. FIG. 5 is a SIMS profile obtained by analyzing the stacked film from bottom to top. In FIG. 5, the horizontal axis represents the distance (depth) from the lower surface of the insulating layer ILI2 as the lower surface is a reference, and the vertical axis represents the boron concentration. The insulating layer ILI2, the semiconductor layer SC2, and the insulating layer GI2 are a silicon oxide film having a film thickness of 200 nm, an IGZO film having a film thickness of 30 nm, and a silicon oxide film having a film thickness of 100 nm, respectively.

FIG. 5 shows the SIMS profile under the condition that the applied voltages of the gate electrode GE2 and boron B are changed. A profile in which the gate electrode GE2 is a molybdenum/tungsten (MoW) film having a film thickness of 300 nm and an applied voltage is 29 keV is defined as PF1. A profile in which the gate electrode GE2 is a stacked film of titanium, aluminum, and titanium (Ti/Al/Ti (TAT)) having a film thickness of 300 nm and an applied voltage is 29 keV is defined as PF2. A profile in which the gate electrode GE2 is a stacked film of titanium, aluminum, and titanium (Ti/Al/Ti (TAT)) having a film thickness of 100 nm and an applied voltage is 29 keV is defined as PF3. A profile in which the gate electrode GE2 is a titanium (Ti) film having a film thickness of 150 nm and an applied voltage is 29 keV is defined as PF4. A profile in which the gate electrode GE2 is a titanium (Ti) film having a film thickness of 150 nm and an applied voltage is 35 keV is defined as PF5.

It is revealed that the profile PF1 has a lower boron concentration in the insulating layer GI2 than the profiles PF3 to PF5.

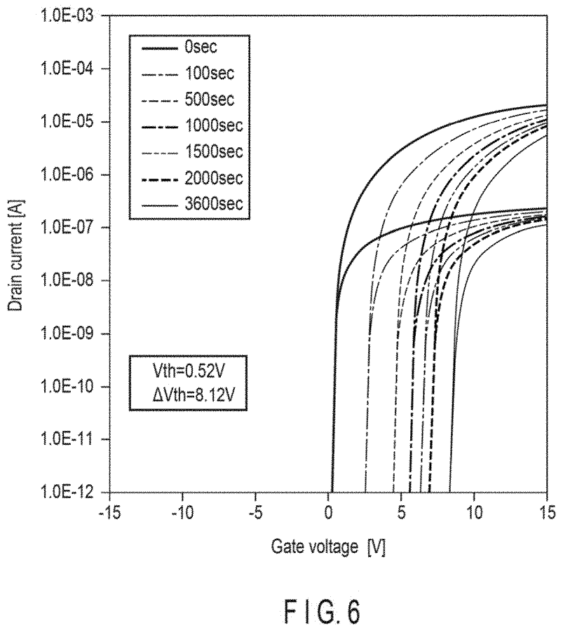

FIGS. 6, 7, 8, and 9 are diagrams showing temporal changes in transistor characteristics under acceleration tests. In the present embodiment, the temporal change in the transistor characteristics of the transistor Tr2 is examined by a positive gate bias temperature stress (Positive Bias Temperature Stress: PBTS) test in which a positive voltage is applied to the gate electrode GE2. FIGS. 6, 7, 8, and 9 show the temporal change in the gate voltage-drain current characteristics (Vg-Id characteristics) in the transistor Tr2 under the conditions of the profiles PF1, PF3, PF4, and PF5, respectively. More specifically, FIGS. 6, 7, 8, and 9 show the Vg-Id characteristics at elapsed times of 0 (zero) seconds, 100 seconds, 500 seconds, 1,000 seconds, 1,500 seconds, 2,000 seconds, and 3,600 seconds.

In FIGS. 6, 7, 8, and 9, two different voltages of 0.1 V and 10 V were applied as the source-drain voltage. In FIGS. 6, 7, 8, and 9, the drain current increases as the source-drain voltage increases.

As described above, in the transistor Tr2 in FIG. 6, the gate electrode GE2 is the molybdenum/tungsten (MoW) film having a film thickness of 300 nm, and the applied voltage of boron B is 29 keV. In FIG. 6, the threshold value Vth at the elapsed time of 0 (zero) seconds, i.e., the initial threshold value Vth was 0.52 V, and the threshold variation amount ΔVth after the test (elapsed time of 3,600 seconds) was 8.12 V.

The threshold variation amount ΔVth of the transistor Tr2 is preferably about 1 V. This is because when the threshold variation amount ΔVth is about 1 V, there is a low possibility that abnormal operation of the transistor Tr2 occurs.

However, in the transistor shown in FIG. 6, the threshold variation amount ΔVth is 8.12 V, which is much larger than 1 V. As described above, the transistor Tr2 having a large threshold variation amount ΔVth might cause degradation in reliability, which is not preferable.

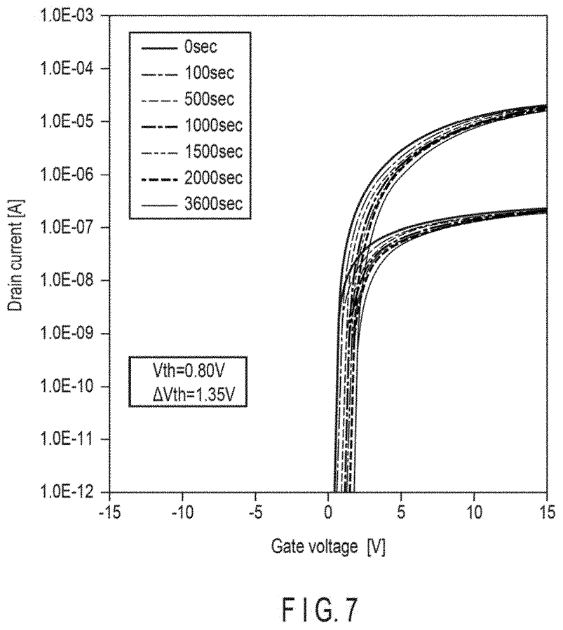

As described above, in the transistor Tr2 in FIG. 7, the gate electrode GE2 is a stacked film of titanium/aluminum/titanium (TAT) having a film thickness of 300 nm, and the applied voltage of boron B is 29 keV. In FIG. 7, the initial threshold amount Vth was 0.80 V, and the threshold variation ΔVth after the test was 1.35 V. The transistor Tr2 having such a small threshold variation amount ΔVth is preferable because degradation in the reliability is suppressed, which is preferable.

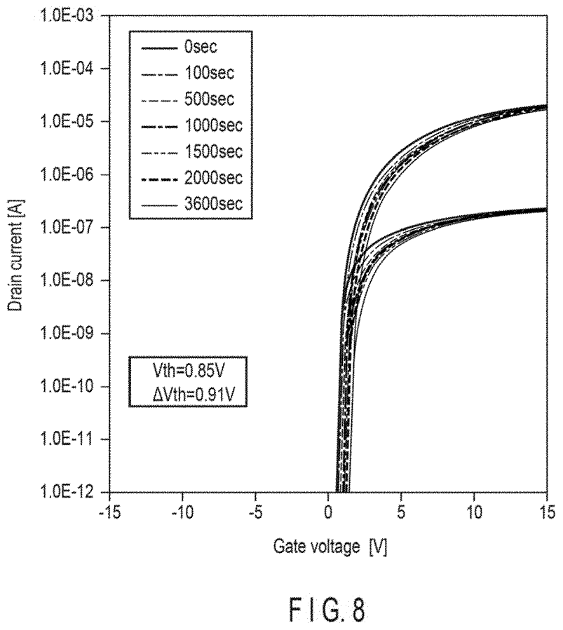

As described above, in the transistor Tr2 in FIG. 8, the gate electrode GE2 is a titanium (Ti) film having a film thickness of 150 nm, and the applied voltage of boron B is 29 keV. In FIG. 8, the initial threshold Vth was 0.85 V, and the threshold variation ΔVth after the test was 0.91 V. The transistor Tr2 having such a small threshold variation amount ΔVth is preferable because degradation in the reliability is suppressed, which is preferable.

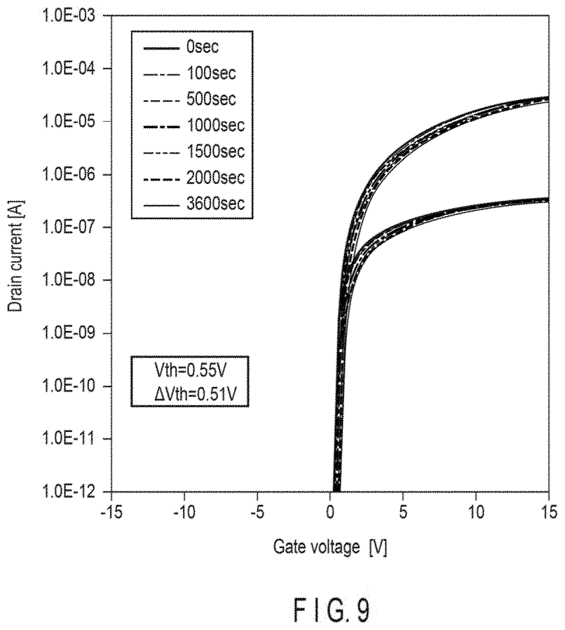

As described above, in the transistor Tr2 in FIG. 9, the gate electrode GE2 is a titanium (Ti) film having a film thickness of 150 nm, and the applied voltage of boron B is 35 keV. In FIG. 9, the initial threshold Vth was 0.55 V, and the threshold variation ΔVth after the test was 0.51 V. The transistor Tr2 having such a small threshold variation amount ΔVth is preferable because degradation in the reliability is suppressed, which is preferable.

Comparing FIG. 8 with FIG. 9, even though the gate electrode GE2 is formed of the same material in the same film thickness, the threshold variation amount ΔVth is smaller when the applied voltage is higher. It is considered that when the applied voltage is high, boron B is injected deeper, the boron concentration of the insulating layer GI2 in the vicinity of the semiconductor layer SC2 increases, and the defect in the region is further repaired.

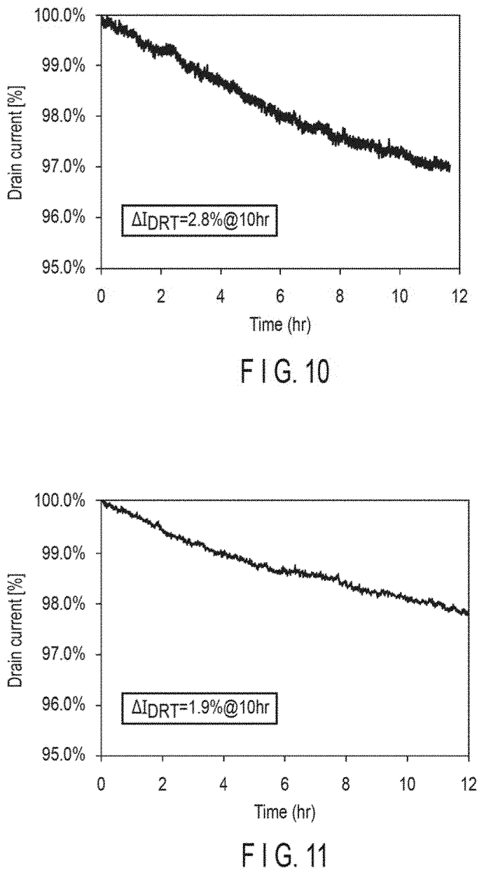

FIGS. 10 and 11 are diagrams showing a temporal change in the drain current when a constant current is continuously carried through the transistor. FIG. 10 shows a temporal change in the drain current in the transistor Tr2 of the profile PF4 (the gate electrode GE2 is a titanium (Ti) film having a film thickness of 150 nm, and the applied voltage of boron B is 29 keV), and FIG. 11 shows a temporal change in the drain current in the transistor Tr2 of the profile PF5 (the gate electrode GE2 is a titanium (Ti) film having a film thickness of 150 nm, and the applied voltage of boron B is 35 keV).

FIG. 10 shows that a change amount ΔI_{DRT} of the drain current decreased by 2.8% in 10 (ten) hours. FIG. 11 shows that the change amount ΔI_{DRT} of the drain current decreased by 1.9% in 10 (ten) hours. It is revealed that the change amount in the drain current of the transistor Tr2 in FIG. 10 (profile PF4) and 11 (profile PF5) is as small as described above. It is revealed that the change amount in the drain current is smaller and the reliability is maintained in the transistor shown in FIG. 11 (profile PF5) than in FIG. 10 (profile PF4).

From the results of the SIMS profiles and the PBTS tests shown in FIGS. 6 to 11, it is revealed that the film thickness of the gate electrode GE2 and the applied voltage at the time of boron B injection are adjusted to improve the reliability of the transistor Tr2. When the film thickness is in the range of 100 nm or more and 150 nm or less, an amount of boron B sufficient for termination of silicon oxide is injected into the insulating layer GI2. As a result, it is possible to repair the defect of the silicon oxide film without causing the depletion of the transistor Tr2. From the above, the reliability of the transistor Tr2 is improved.

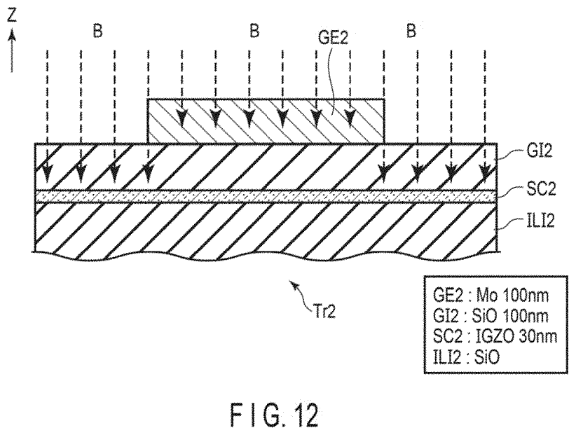

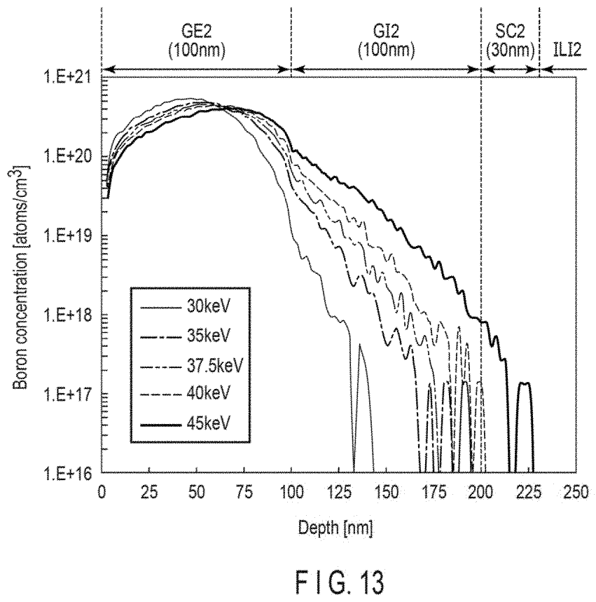

FIG. 12 is a diagram showing the configuration of a stack of the transistor Tr2, and FIG. 13 is a diagram showing a simulation result of boron injection in the configuration of the stack. In the transistor Tr2 shown in FIG. 12, as the insulating layer ILI2, the semiconductor layer SC2, the insulating layer GI2, and the gate electrode GE2, silicon oxide (SiO), an IGZO film having a film thickness of 30 nm, a silicon oxide (SiO) film having a film thickness of 100 nm, and a molybdenum (Mo) film having a film thickness of 100 nm are stacked in this order from the bottom. As shown in FIG. 12, boron B is injected from above.

FIG. 13 is a simulation result obtained by analyzing the configuration of the stack from top to bottom. In FIG. 13, the horizontal axis represents the distance (depth) from the upper surface of the gate electrode GE2 as the upper surface is a reference, and the vertical axis represents the boron concentration.

In FIG. 13, the applied voltage of boron B is 30 keV, 35 keV, 37.5 keV, 40 keV, and 45 keV. As shown in FIG. 13, at the above applied voltage, the boron concentration in the insulating layer GI2 is in a range of 1E+16 [atoms/cm³] or more. However, it is revealed that boron B is injected up to the semiconductor layer SC2 at an applied voltage of 45 keV. Therefore, in the case in which the gate electrode GE2 is a molybdenum film having a film thickness of 100 nm, the applied voltage of boron B is preferably in a range of 30 keV or more and 40 keV or less.

As shown in FIG. 13, the gate electrode GE2 contains boron in a range of 5E+19 [atoms/cm³] or more and 5E+20 [atoms/cm³] or less.

According to the present embodiment, it is possible to obtain the transistor Tr2 with improved reliability. With the improved reliability of the transistor Tr2, it is possible to improve the reliability of the display device DSP including the transistor Tr2.

### Configuration Example 1

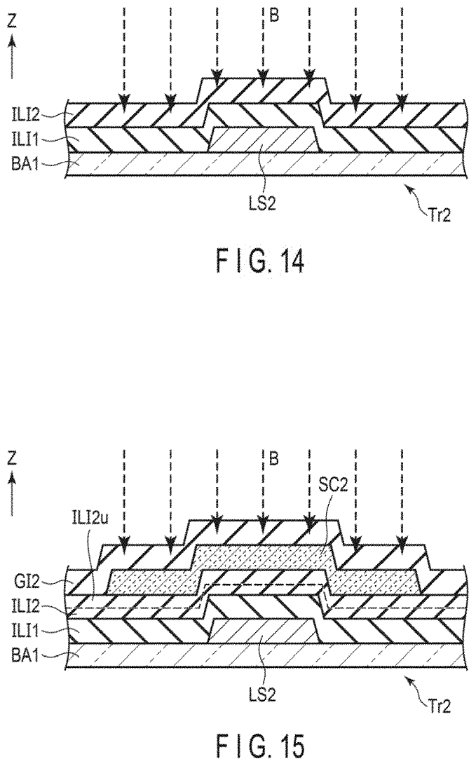

FIG. 14 is a cross-sectional view showing a configuration example of a semiconductor device according to an embodiment. The configuration example shown in FIG. 14 is different from the configuration example shown in FIG. 3 in that boron is injected twice.

FIGS. 14 and 15 are cross-sectional views showing the manufacturing process of the transistor Tr2. First, the light-shielding layer LS2, the insulating layer ILI1, and the insulating layer ILI2 are formed on the base material BA1. Similarly to FIG. 2, an insulating layer may be provided between the base material BA1 and the light-shielding layer LS2. The insulating layer ILI2 is a silicon oxide film.

After forming the insulating layer ILI2, boron B is injected. The injection process is also referred to as a first injection process. In the first injection process, boron B is applied to the insulating layer ILI2 (see FIG. 14).

More specifically, boron B is injected into a region of the insulating layer ILI2 in contact with the semiconductor layer SC2 described later. The applied voltage may be set such that boron B is injected into the region.

After the first injection process, the semiconductor layer SC2 is formed on the insulating layer ILI2. The insulating layer GI2 is provided covering the semiconductor layer SC2 and in contact with the semiconductor layer SC2 and the insulating layer ILI2. The insulating layer GI2 is a silicon oxide film.

In the first injection process, a region of the insulating layer ILI2 into which boron B is injected is referred to as ILI2u. As described above, the semiconductor layer SC2 and the region ILI2u are in contact with each other. The region ILI2u is located in the vicinity of the interface between the insulating layer ILI2 and the semiconductor layer SC2. The region ILI2u is the region of the upper layer of the insulating layer ILI2. The boron concentration of the insulating layer ILI2, particularly the region ILI2u may be in a range of 1E+16 [atoms/cm³] or more as in the example shown in FIG. 13.

After forming the insulating layer GI2, boron B is injected. The injection process is also referred to as a second injection process. In the second injection process, boron B is injected into the insulating layer GI2 (see FIG. 15). The boron concentration of the insulating layer GI2 may be in a range of 1E+16 [atoms/cm³] or more, similarly to the example shown in FIG. 13.

With the injection of boron B into the insulating layers GI2 and ILI2 that are in contact with the semiconductor layer SC2 above and below, it is possible to decrease the defect level due to excessive oxygen in the insulating layers ILI2 and GI2 without increasing the defect of the semiconductor layer SC2. As a result, it is possible to improve the reliability of the transistor Tr2.

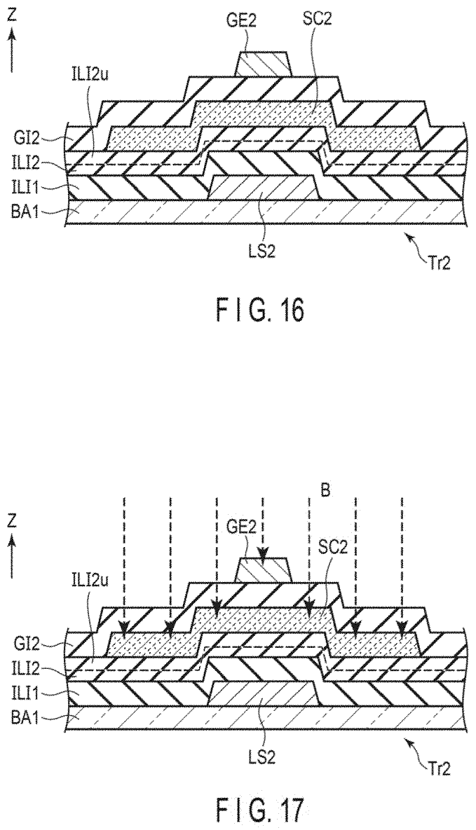

FIGS. 16, 17, and 18 are cross-sectional views showing the manufacturing process of the transistor Tr2. On the insulating layer GI2, a metal film is formed and the metal film is shaped to form the gate electrode GE2 (see FIG. 16).

Subsequently, boron B is injected into the semiconductor layer SC2 using the gate electrode GE2 as a mask (see FIG. 17).

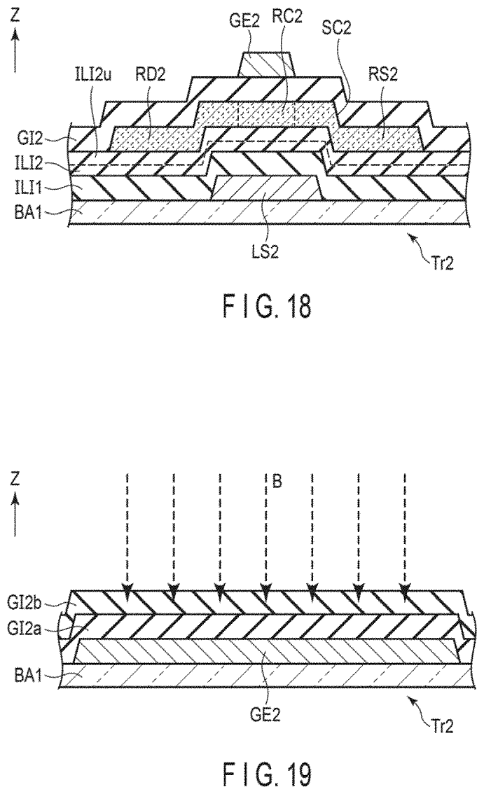

In a region of the semiconductor layer SC2 that does not overlap the gate electrode GE2, boron B is injected to decrease resistance. The low resistance region is used as the source region RS2 and the drain region RD2 (see FIG. 18).

Into the region of the semiconductor layer SC2 overlapping the gate electrode GE2, no Boron B is injected. This region is used as the channel forming region RC2.

Incidentally, depending on the defect amounts of the insulating layers ILI2 and GI2, boron B may be injected into one of the insulating layers ILI2 and GI2, for example, only the insulating layer ILI2.

Also in the present configuration example, the same effect as that of the embodiment is exerted.

### Configuration Example 2

FIG. 19 is a cross-sectional view showing a configuration example of a semiconductor device according to an embodiment. The configuration example shown in FIG. 19 is different from the configuration example shown in FIG. 3 in that the transistor Tr2 is a bottom gate type.

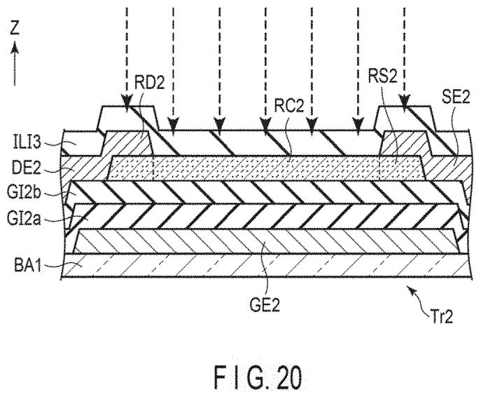

FIGS. 19 and 20 are cross-sectional views showing the manufacturing process of the transistor Tr2. First, the gate electrode GE2, an insulating layer GI2a, and an insulating layer GI2b are formed on the base material BA1. Similarly to FIG. 2, an insulating layer may be provided between the base material BA1 and the light-shielding layer LS2. The insulating layer GI2b is in contact with the semiconductor layer SC2, which is formed in a later process. The insulating layer GI2b may be silicon oxide. Instead of the two insulating layers GI2a and GI2b, only one insulating layer (referred to as the insulating layer GI2) may be formed.

After forming the insulating layer GI2b, boron B is injected. The injection process is referred to as a first injection process of the present configuration example. Similarly to the embodiment, the boron concentration in the insulating layer GI2b may be in a range of 1E+16 [atoms/cm³] or more. As a result, it is possible to decrease the defect level due to excessive oxygen in the insulating layer GI2b.

The concentration of boron may be in the above range in the insulating layer GI2b as well as in two insulating layers (which is the insulating layer GI2) including the insulating layer GI2b and the insulating layer GI2a. Also in the case in which only one insulating layer is formed, the boron concentration may be in the above range.

Subsequently, the semiconductor layer SC2 is formed on the insulating layer GI2b. The semiconductor layer SC2 overlaps the gate electrode GE2 with the insulating layers GI2 (GI2a and GI2b) interposed.

With the semiconductor layer SC2 covered, a metal film is formed, and a part of the metal film is removed to form the source electrode SE2 and the drain electrode DE2. In a region of the semiconductor layer SC2 overlapping the source electrode SE2 is the source region RS2, and a region overlapping the drain electrode DE2 is the drain region RD2. The channel forming region RC2 is provided between the source region RS2 and the drain region RD2.

When a part of the metal film is removed, a part of the upper layer of the channel forming region RC2 may be removed.

The insulating layer ILI3 is formed covering the insulating layer GI2b (insulating layer GI2), the semiconductor layer SC2, the source electrode SE2, and the drain electrode DE2. The insulating layer ILI3 is in contact with the semiconductor layer SC2. The insulating layer ILI3 may be silicon oxide.

After forming the insulating layer ILI3, boron B is injected. The injection process is referred to as a second injection process of the present configuration example. The boron concentration in the insulating layer ILI3 may be in a range of 1E+16 [atoms/cm³] or more. As a result, it is possible to decrease the defect level due to excessive oxygen in the insulating layer ILI3.

In the second injection process, the applied voltage at the time of injection is determined such that boron B is not injected into the semiconductor layer SC2 and boron B is injected into the insulating layer ILI3.

Also in the present configuration example, the same effect as that of the embodiment is exerted.

In the present disclosure, the insulating layer in contact with the semiconductor layer SC2 and formed under the semiconductor layer SC2 is referred to as a first insulating layer. The insulating layer in contact with the semiconductor layer SC2 and formed on the semiconductor layer SC2 is referred to as a second insulating layer.

In the transistor Tr2 shown in FIGS. 14 to 18, the insulating layers ILI2 and GI2 correspond to the first insulating layer and the second insulating layer, respectively. In the transistor Tr2 shown in FIGS. 19 and 20, the insulating layer GI2 and the insulating layer ILI3 correspond to the first insulating layer and the second insulating layer, respectively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming an oxide semiconductor layer;
forming a gate insulating layer in contact with the oxide semiconductor layer and covering the oxide semiconductor layer;
forming a gate electrode on the gate insulating layer so as to overlap the oxide semiconductor layer; and
injecting boron through the gate electrode and the gate insulating layer after forming the gate electrode, wherein
a boron concentration included in a region of the gate insulating layer overlapping the gate electrode is in a range of 1E+16 [atoms/cm³] or more.

2. The method of manufacturing a semiconductor device according to claim 1, wherein the gate insulating layer is a silicon oxide film.

3. The method of manufacturing a semiconductor device according to claim 1, wherein an applied voltage at injecting the boron is in a range of 30 keV or more and 40 keV or less.

4. A method of manufacturing a semiconductor device comprising:
forming a first insulating layer;
injecting boron into the first insulating layer;
forming an oxide semiconductor layer in contact with the first insulating layer into which the boron is injected;
forming a second insulating layer in contact with the oxide semiconductor layer and covering the first insulating layer and the oxide semiconductor layer;
injecting boron into the second insulating layer; and
forming a gate electrode on the second insulating layer into which the boron is injected, the gate electrode being overlapping the oxide semiconductor layer, wherein
a boron concentration included in the first insulating layer and the second insulating layer is in a range of 1E+16 [atoms/cm³] or more.

5. The method of manufacturing a semiconductor device according to claim 4, wherein the first insulating layer and the second insulating layer are a silicon oxide film.

6. The method of manufacturing a semiconductor device according to claim 4, wherein an applied voltage at which the boron is injected is in a range of 30 keV or more and 40 keV or less.

7. A method of manufacturing a semiconductor device comprising:
forming a gate electrode;
forming a first insulating layer covering the gate electrode;
injecting boron into the first insulating layer;
forming an oxide semiconductor layer in contact with the first insulating layer into which the boron is injected;
forming a source electrode and a drain electrode overlapping a part of the oxide semiconductor layer;
forming a second insulating layer in contact with the oxide semiconductor layer and covering the oxide semiconductor layer, the source electrode, and the drain electrode; and
injecting boron into the second insulating layer, wherein
a boron concentration included in the first insulating layer and the second insulating layer is in a range of 1E+16 [atoms/cm³] or more.

8. The method of manufacturing a semiconductor device according to claim 7, wherein the first insulating layer and the second insulating layer are a silicon oxide film.

9. The method of manufacturing a semiconductor device according to claim 7, wherein an applied voltage at which injecting the boron is in a range of 30 keV or more and 40 keV or less.
